(19) United States
(12) Patent Application Publication
(10) Pub. No.: US 2021/0010595 A1
(43) Pub. Date: Jan. 14, 2021

(54) CUSHION FOR IRREGULAR CABLE SHAPES

(71) Applicant: CommScope Technologies LLC, Hickory, NC (US)

(72) Inventor: Ronald A. Vaccaro, Taylorsville, NC (US)

(21) Appl. No.: 16/915,080

(22) Filed: Jun. 29, 2020

Related U.S. Application Data
(60) Provisional application No. 62/871,996, filed on Jul. 9, 2019.

(51) Int. Cl. F16J 15/02

(52) U.S. Cl. CPC F16J 15/022

(57) ABSTRACT

A cushion for a sealing assembly includes: an inner ring defining a central bore; an outer ring; a transition section connecting the inner and outer rings, an inner sealing rib jutting inward into the cylindrical bore, and hoop members attached above and below the inner ring. A cable is inserted into the cushion, causing at least one of the hoop members to bend inward and create a seal, while another seal is formed via the engagement between the cable and the inner sealing rib.

### RELATED APPLICATION

This application claims priority from and the benefit of U.S. Provisional Patent Application No. 62/871,996, filed Jul. 9, 2019, the disclosure of which is hereby incorporated herein by reference in its entirety.

### FIELD OF THE INVENTION

The invention relates generally to a device for environmentally sealing and securing cable connections.

### BACKGROUND

Interconnection junctions, such as the interconnection between a cable and a piece of electronic equipment, may be subject to degradation due to fluid ingress. Often boots, grommets, glands, or other interconnection devices are designed to surround the interconnection to prevent fluid entry. The boot or grommet is then mounted in the wall of the enclosure of the equipment. The bores designed to receive cables in boots and other interconnection devices are typically circular, as most cables have a circular cross-section.

However, in many installations, multiple cables, such as trunk power cables and hybrid fiber and power cables, are bundled together and surrounded by a single sheath. These cable bundles may have non-circular cross-sections that more closely resemble a triangle or a square. Non-cylindrical cables present a unique problem in the designation of the size of the bore hole in the sealing device. Because square and triangular cross-sectional cables lack a consistent diameter, a cylindrical bore may not provide sufficient pressure on the cable jacket to seal properly. Thus, there may be a need for the bore of the sealing assembly to accommodate cables of varying width.

### SUMMARY

As a first aspect, embodiments of the invention are directed to a cushion for a cable sealing assembly formed of a polymeric material, comprising: an inner ring, an outer ring, and a compressible transition section connecting the inner and outer rings. The inner ring defines a central bore through the cushion. The transition section has a profile including at least one ridge with a recess defined therein.

As a second aspect, embodiments of the invention are directed to an interconnection assembly, comprising: a cushion and a cable. The cushion comprises: an inner ring, an outer ring, and a transition section. The inner ring of the cushion defines a central bore through the cushion. The transition section of the cushion has a profile including at least one ridge with a recess defined therein. The cable is inserted into the bore of the cushion and engages with the walls of the inner ring.

As a third aspect, embodiments of the invention are directed to a cushion for a cable sealing assembly formed of a polymeric material, comprising: an inner ring, an outer ring, and a compressible transition section connecting the inner and outer rings. The inner ring defines a central bore through the cushion. The inner ring comprises at least one hoop member extending above the cushion.

### BRIEF DESCRIPTION OF THE FIGURES

FIG. 1 is a perspective view of a cushion employed in a gland according to an embodiment of the invention.

FIG. 2 is a top view of the cushion of FIG. 1.

FIG. 3 is a section view of the cushion of FIG. 2 taken along the line 3-3 with a cable mounted therein.

FIG. 4 is an enlarged view of the cable and cushion of FIG. 3, showing engagement of the hoop members.

FIG. 5 is an enlarged view of the transition section of the cushion of FIG. 3.

FIG. 6 is a section view of the cable and cushion assembly of FIG. 3, in which the transition section has been radially compressed.

FIG. 7 is an enlarged view of a hoop member according to an embodiment of the invention.

FIG. 8 is a section view of another cable and cushion assembly according to embodiments of the invention, in which the cushion has a plurality of inner sealing ribs.

FIG. 9 is a section view of a further cable and cushion assembly according to embodiments of the invention, wherein the transition section has a different cross-sectional pattern than that in FIG. 3.

FIG. 10 is a section view of a still further cable and cushion assembly according to embodiments of the invention, wherein the transition section has a sinusoidal cross-section.

FIG. 11 is a section view of a yet still further cable and cushion assembly according to embodiments of the invention, wherein the transition section has a continuously rising profile.

### DETAILED DESCRIPTION

The present invention is described with reference to the accompanying drawings, in which certain embodiments of the invention are shown. This invention may, however, be embodied in many different forms and should not be construed as limited to the embodiments that are pictured and described herein; rather, these embodiments are provided so that this disclosure will be thorough and complete, and will fully convey the scope of the invention to those skilled in the art. It will also be appreciated that the embodiments disclosed herein can be combined in any way and/or combination to provide many additional embodiments.

Like numbers refer to like elements throughout. In the figures, certain layers, components or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

Unless otherwise defined, all technical and scientific terms that are used in this disclosure have the same meaning as commonly understood by one of ordinary skill in the art to which this invention belongs. The terminology used in the below description is for the purpose of describing particular embodiments only and is not intended to be limiting of the invention. As used in this disclosure, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “on,” “attached to,” “connected to,” “coupled with,” “contacting,” etc., another element, it can be directly on, attached to connected to, coupled with or contacting the other element or intervening elements may also be present. In contrast, when an element is referred to as being, for example, “directly on,” “directly attached to,” “directly connected to,” “directly coupled with,” or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “above”, “over”, “upper”, “lower”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

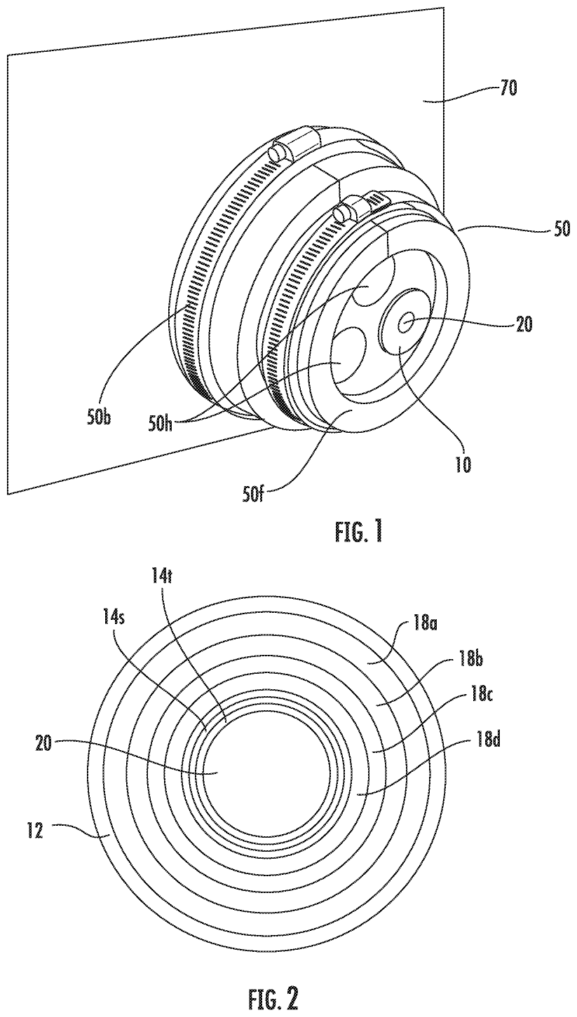

Referring now to the drawings, a cushion, designated broadly at 10, is shown in FIG. 1-6. As best seen in FIGS. 2 and 3, the cushion 10 comprises an outer ring 12 and an inner ring 14, such that the inner ring 14 defines a central bore 20. A transition section 18 extends radially outward from the inner ring 14 until merging with the outer ring 12. These components will be discussed in greater detail below.

FIG. 1 depicts an assembly wherein the cushion 10 may be employed. The assembly of FIG. 1 comprises a boot or gland 50, which may be mounted in the wall of an enclosure 70. As illustrated in FIG. 1, a plurality of holes 50h may be present in each gland 50, such that multiple cushions 10 may be included in the same gland 50. Furthermore, the gland 50 may comprise a front section 50f attached to a back section 50b, where both sections are substantially cylindrical. A circular recess may be embossed on an exposed face of the gland 50, on which the holes 50h are present.

As illustrated in FIGS. 2 and 3, the cushion 10 may be substantially annular in shape and configured such that it may fit in the circular holes 50h of the gland 50, as depicted in FIG. 1. The central bore 20 may be substantially circular and substantially concentric with the cushion 10.

The inner ring 14 includes a sealing rib 16 extending radially inward from the inner ring 14 into the central bore 20. The transition section 18 extends radially outward from the inner ring until merging with the outer ring 12. As shown in FIG. 5, the transition section 18 includes, in order of distance from the inner ring 14, an initial ring 18a, a downwardly extending ridge 18b, an upwardly extending ridge 18c, and a final ring 18d. Ridges 18b, 18c may each include a recess 18r that matches the profile of the ridge 18b, 18c. As illustrated in FIG. 3, the cross-section of the transition section 18 therefore may resemble a “square wave.”

The transition section 18 may be formed of any number of materials, but is typically formed of an elastomeric material, such as rubber, that can recover its original shape after significant deformation. In some embodiments, the transition section 18 may be formed of an ethylene propylene diene monomer (EPDM). Furthermore, in some embodiments the transition section 18 may be formed via injection molding.

In the illustrated embodiment, the outer ring 12 and the outer portion of the inner ring 14 have substantially the same height (i.e., the vertical dimension as seen in FIG. 3). The inner ring 14 may include, adjacent to its outer portion, circular slits 14s, which extend axially into the edges of the inner ring 14. Furthermore, adjacent to the circular slits 14s, the inner ring 14 includes upper and lower hoop members 14t, which have substantially the same inner diameter as that of the inner ring 14, and project axially above and below the cushion 10.

Referring to FIG. 3, when a cable 60 of diameter greater than the initial diameter of the bore 20 is inserted into the cushion 10, the transition section 18 may compress, causing the inner ring 14 to expand radially outward toward the outer ring 12. As illustrated in FIG. 6, during compression, the profile of the transition section 18 may change, as the recesses 18r may narrow and the rings 18a, 18d may bend toward the inner 14 and outer rings 12, respectively. This compression of the transition section 18 increases the diameter of the bore 20, thereby allowing the cable 60 to fit within the bore 20 while the cushion fits tightly around the cable 60. In some embodiments, the transition section 18 may be able to compress radially between about ⅛ and 3/16 inch. When the cable 60 is removed from the bore 20 of the cushion 10, the diameter of the bore 20 may return to substantially the same size as prior to cable insertion. Additionally, upon the removal of the cable 60, the cross-section of the transition section 18 may return to substantially the same shape as before insertion, and the inner ring 14 and outer ring 12 may have substantially the same distance between them as before insertion.

Notably, the ability of the transition section 18 to be compressed enables it to seal non-circular cables. More specifically, portions of the inner ring 14 that overlie radially larger ones of the cable can expand radially outward as needed, due to the compressibility of the transition section. Thus, the cushion 10 can provide sealing between the cable 60 and the inner ring 14, even for non-cylindrical cables.

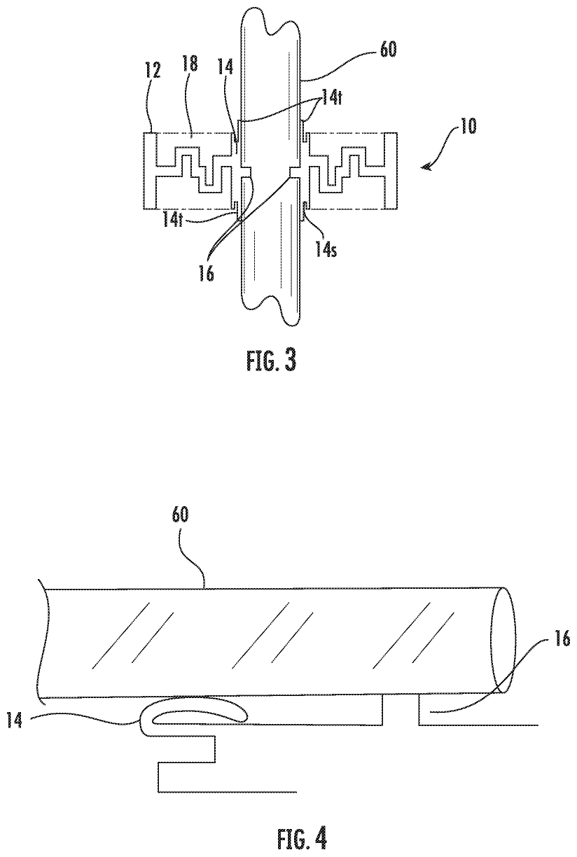

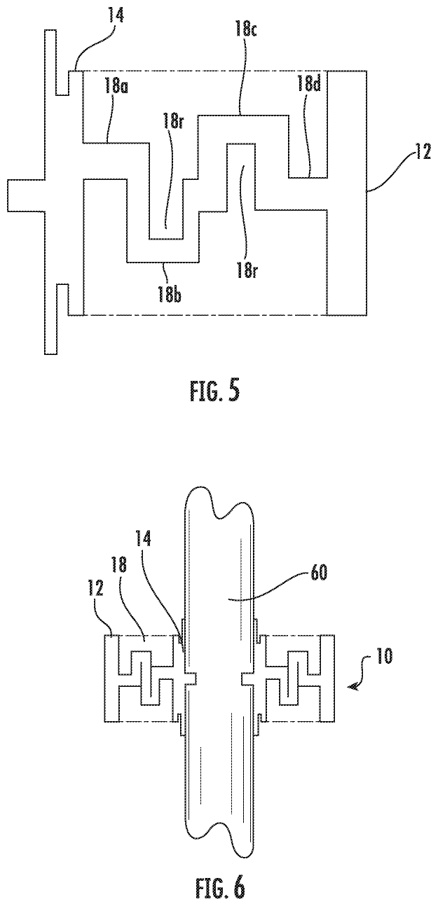

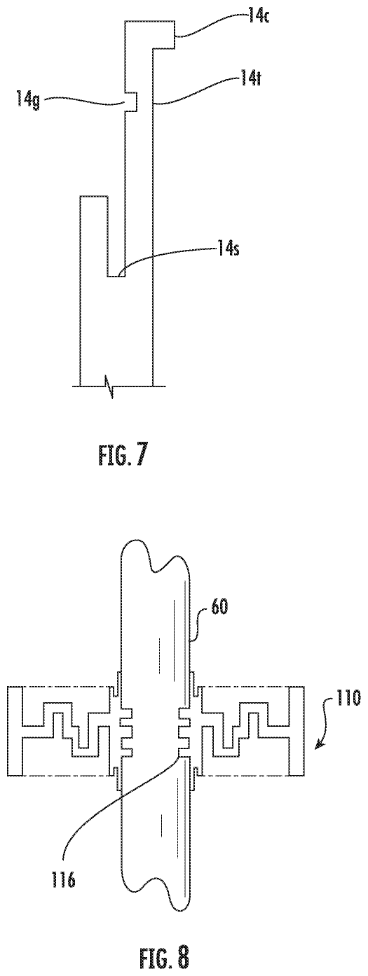

As can be seen in FIG. 4, on the side of the cushion 10 where the cable 60 is inserted into the central bore 20, the free end of the nearest hoop member 14t may fold inward and create and additional seal around the cable 60. In some embodiments, as can be seen in FIG. 7, each hoop member 14t may comprise at least one circumferential groove 14g, which may allow the hoop members 14t to more easily bend inward. The tip of one or more of the hoop members 14t may also include a catching projection 14c projecting radially inward into the bore 20. The catching projection 14c may assist in ensuring that the cable 60 properly catches and folds the hoop members 14t upon insertion. Furthermore, each hoop member 14t may include one or axial slits, defining multiple sections, or “petals,” of each hoop member 14t. The slits may be configured such that the folding of one section of a hoop member 14t may not necessarily be coupled with the folding of another section. The slits may be straight or tapered.

Additionally, when the cable 60 is inserted into the bore 20, the cable 60 may compress the inner sealing rib 16, thereby creating another seal location around the cable 60 at the point of the rib 16. The seals created by the hoop members 40t and the inner sealing rib 16 may be sufficiently tight so as to prevent water ingress between the cable 60 and the cushion 10 and into the back section 50b of the gland 50.

The cushion 10 is configured such that it may receive cables 60 with substantially circular cross-sections, but also those with less rounded exteriors. Examples of non-cylindrical cables capable of being inserted into and sealed by the cushion 10 include triangular- and square-shaped cables.

In the embodiment depicted in FIG. 3, the cushion 10 comprises a single inner sealing rib 16. However, in some embodiments, as depicted in FIG. 8, a cushion 110 may comprise a plurality of inner sealing ribs 116. Furthermore, in some other embodiments, the cushion 10 may not comprise any inner sealing ribs 16, and the upper or lower hoop member 14t may provide a primary method for sealing the cable 60. In other embodiments, the inner ring 14 may not comprise any hoop members 14t or slits 14s and therefore the entirety of the inner ring 14 may be substantially the same height as the outer ring 12. Therefore, the inner sealing rib 16 may provide a primary method for sealing the cable 60.

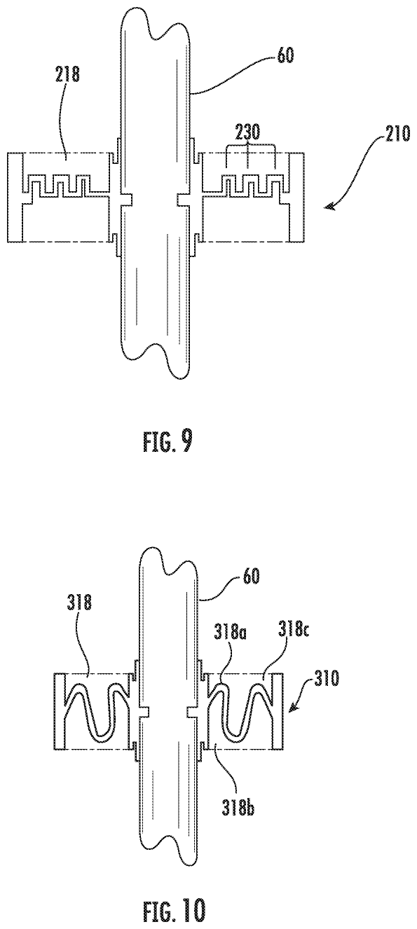

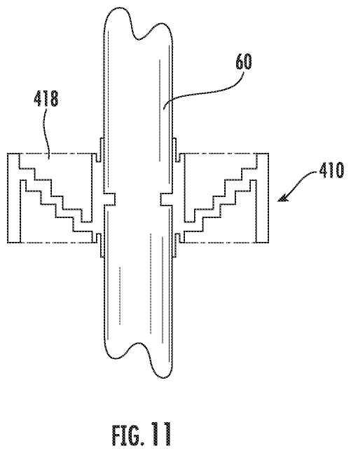

Although in the embodiment illustrated in FIG. 3, the cross-section of the transition section 18 may resemble a square wave, with upwardly and downwardly extending ridges 18b, 18c, in other embodiments, as in FIG. 9, a cushion 210 may include a transition section 218 with only upwardly or only downwardly extending ridges 230. In other embodiments, as illustrated in FIG. 10, a cushion 310 may include a sinuous transition section 318 with ridges 318a, 318b, 318c being rounded rather than squared off. In still other embodiments, as shown in FIG. 11, the profile of the transition section 418 of a cushion 410 may be continuously rising away from the inner ring and may resemble a series of “steps”.

Those of skill in this art will appreciate that the cushions 10 discussed above may vary in configuration. For example, although each of the cushions 10, 110, 210, 310, 410 is shown with either one or three inner sealing ribs 16, 116, fewer or more ribs may also be employed. Also, the number of ridges of the transition sections 18 depicted in FIGS. 3, 9 and 10 are not limited to only those quantities depicted in the figures, nor are the ridges 18 limited to those shapes; any transition section with compressible ridges may be employed (e.g., an “accordion” shape may be used). Furthermore, those of skill in this art will appreciate that the cushion 10 is not limited to being employed in only those interconnection devices resembling the gland 50 in FIG. 1. Instead, the cushion 10 may be employed in a wide variety of interconnection devices.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein.

That which is claimed is:

1. A cushion for a cable sealing assembly formed of a polymeric material, comprising:
an inner ring, defining a bore;
an outer ring; and
a compressible transition section connecting the inner and outer rings, wherein the transition section has a profile including at least one ridge with a recess defined therein.

2. The cushion defined in claim 1, further comprising at least one rib attached to the inner ring that extends radially inward into the bore.

3. The cushion defined in claim 1, wherein the polymeric material is an elastomeric material.

4. The cushion defined in claim 3, wherein the elastomeric material comprises ethylene propylene diene monomer.

5. The cushion defined in claim 1, wherein the cushion is formed via injection molding.

6. The cushion defined in claim 1, wherein the inner ring includes at least one hoop member extending axially outward of the inner ring.

7. The cushion defined in claim 6, wherein the at least one hoop member comprises at least one circumferential groove.

8. The cushion defined in claim 6, wherein the at least one hoop member has an inner diameter substantially equal to an inner diameter of the inner ring.

9. The cushion defined in claim 1, wherein the inner ring has a circular slit extending axially into the inner ring.

10. The cushion defined in claim 1, wherein the at least one ridge is two ridges.

11. The cushion defined in claim 10, wherein the transition section has a profile resembling a square wave.

12. The cushion defined in claim 10, wherein the transition section has a profile that is substantially sinusoidal.

13. The cushion defined in claim 10, wherein the first ridge extends in a first axial direction and the second ridge extends a second, opposing axial direction.

14. An interconnection assembly, comprising:
(a) a cushion formed of a polymeric material, wherein the cushion comprises an inner ring, defining a bore; an outer ring; and a transition section connecting the inner and outer rings, wherein the transition section has a profile including at least one ridge with a recess defined therein; and
(b) a cable inserted into the bore of the cushion and engaged with the walls of the inner ring.

15. The assembly defined in claim 14, wherein the cable has a non-circular cross-section.

16. The assembly defined in claim 14, wherein the polymeric material is an elastomeric material.

17. The assembly defined in claim 16, wherein the elastomeric material comprises an ethylene propylene diene monomer.

18. The assembly defined in claim 14, wherein the cushion is formed via injection molding.

19. The assembly defined in claim 14, wherein the cushion further comprises at least one rib attached to the inner ring that extends radially inward into the bore.

20. A cushion for a cable sealing assembly formed of a polymeric material, comprising:
an inner ring, defining a bore;
an outer ring; and
a compressible transition section connecting the inner and outer rings;
wherein the cushion comprises at least one hoop member extending axially outward of the inner ring.
